(19) United States
(12) Patent Application Publication
(10) Pub. No.: US 2025/0193085 A1
(43) Pub. Date: Jun. 12, 2025

(54) Assembling a Digital Twin of a Telecommunication Network

(71) Applicants: Koninklijke KPN N.V., Rotterdam (NL); Nederlandse Organisatie Voor Toegepast-Natuurwetenschappelijk Onderzoek TNO, 's-Gravenhage (NL)

(72) Inventors: Kallol Das, Waddinxveen (NL); Toni Dimitrovski, Boskoop (NL); Remco Litjens, Voorschoten (NL); Haibin Zhang, Voorburg (NL)

(21) Appl. No.: 18/844,889

(22) PCT Filed: Mar. 9, 2023
(86) PCT No.: PCT/EP2023/055985

§ 371 Date: Sep. 6, 2024

(30) Foreign Application Priority Data
Mar. 14, 2022 (EP) 22161803

(51) Int. Cl. H04L 41/14; G06F 30/27; H04L 41/16; H04W 24/06

(52) U.S. Cl. CPC H04L 41/145; G06F 30/27; H04L 41/16; H04W 24/06

(57) ABSTRACT

A system for performing simulations on a digital twin (1) of a telecommunication network is configured to determine a assessment accuracy with respect to one or more performance indicators and/or determine a maximum assessment duration, select a simulation model (13-15,23-25,33-35,43-45) for each of a plurality of components (3-8) of the digital twin based on at least one of the minimum assessment accuracy and the maximum assessment duration, assemble the selected simulation models (13,14,23,33,43) into the digital twin, and perform the simulations on the digital twin.

### FIELD OF THE INVENTION

The invention relates to a system for performing simulations on a digital twin of a telecommunication network.

The invention further relates to a method of performing simulations on a digital twin of a telecommunication network.

The invention also relates to computer program products enabling a computer system to perform such a method.

### BACKGROUND OF THE INVENTION

The concepts of ‘cyber-physical fusion’ and ‘digital twins’ are applied/under development in a variety of domains including manufacturing, logistics and smart cities. The basic idea is for a physical object to have a digital representation upon which scenario-based experiments can be conducted in a manual or automated fashion, e.g. in order to predict and analyze the behavior/response of the object before applying selected adaptations to the physical object itself.

Various models/tools exist in the mobile networking context for the purpose of network planning, optimization and technology/feature development. Widely used are e.g. radio network planning tools, system- and link-level simulators, with distinct degrees of modelling accuracy/complexity and evaluation speed and consequently different scopes of usage. At the one extreme, a link-level simulator models transmission, channel and reception aspects in great detail and consequently addresses only a single radio link in isolation. At the other extreme, a radio network planning tool typically involves rather simplified modelling of the network technology to allow assessment of a relatively large part of an operational network with many active users. Tools such as these are generally used by human experts to carry out experiments in order to derive actions that are subsequently, in a non-automated fashion, applied in the operational network.

In the context of Self-Organizing Networks (SON), fully automated closed-loop control mechanisms have been developed and implemented, typically characterized by a continuous cycle of measurements, algorithmic processing thereof and applying a derived configuration change to the operational network. The underlying algorithms may be if-then-else type engineering rules or still relatively simple Artificial Intelligence (AI)/Machine Learning (ML)-based solutions, which are not nearly as evolved as foreseen digital twin-based solutions.

The paper “Digital twin for 5G and beyond” by H. X. Nguyen, R. Trestian, D. To and M. Tatipamula, IEEE Communications Magazine, vol. 59, no. 2, 2021, gives a general overview of the digital twin concept in the context of mobile communication networks and how it can be used in 5G network optimization. The authors present the digital twin as containing a virtual model which is self-learning (using AI/ML techniques) on a real-time basis. The paper further describes the digital twin as an integration of distinct models representing different parts of the network.

An online blog of Ericsson titled “The future of digital twins: what will they mean for mobile networks?” (https://www.ericsson.com/en/blog/2021/7/future-digital-twins-in-mobile-networks) addresses the tradeoff between complexity, accuracy and the computational resources needed to perform simulations when applying the digital twin concept in mobile communication networks. The blog suggests having a mix of different models with different complexities depending on the use case at hand, the network domain of interest, and the level of detail needed. However, the blog does not disclose how this can be realized and this is not evident from the blog.

Currently, there is no ‘one size fits all’ solution to digitally twinning a mobile network or other telecommunication network; simulations performed by a digital twin may be too slow in a first situation but not in a second situation or may be too inaccurate in a first situation but not in a second situation.

### SUMMARY OF THE INVENTION

It is a first objective of the invention to provide a system, which can create a digital twin which suits the situation at hand.

It is a second objective of the invention to provide a method, which can be used to create a digital twin which suits the situation at hand.

In a first aspect of the invention, a system for performing simulations on a digital twin of a telecommunication network includes at least one processor configured to determine a minimum assessment accuracy with respect to one or more performance indicators and/or determine a maximum assessment duration, select a simulation model for each of a plurality of components of the digital twin based on at least one of the minimum assessment accuracy and the maximum assessment duration, assemble the selected simulation models into the digital twin, and perform the simulations on the digital twin.

With this system, a digital twin may be assembled from more complex components and/or more components in situations where assessment accuracy is important and/or assessment duration is not/less important and a digital twin may be assembled from less complex components and/or less components when assessment duration is important and/or assessment accuracy is less important. In this way, a digital twin may be created which suits the situation at hand. Examples of performance indicators are throughput, latency, and coverage probability. The simulations are typically performed with different settings of a configuration parameter. The simulation models are normally determined jointly and not (separately) per component. Each component has a component type. The telecommunication network may be a mobile communication network or a cable TV network, for example.

The at least one processor may be configured to select the simulation model for each of the plurality of components of the digital twin based on at least one of the minimum assessment accuracy and the maximum assessment duration by determining a quantity of the plurality of components based on at least one of the minimum assessment accuracy and the maximum assessment duration and selecting a simulation model for each of the plurality of components. Thus, a digital twin may be assembled from more components in situations where assessment accuracy is important and/or assessment duration is not/less important. For example, a relatively high quantity of components may be selected for component types that are most relevant for a problem at hand.

Optionally, for at least one of the plurality of components, a component type of a respective component may be associated with a plurality of simulation models of different degrees of complexity. The at least one processor may then be configured to select the simulation model for each of the plurality of components of the digital twin based on at least one of the minimum assessment accuracy and the maximum assessment duration by (jointly) selecting at least one simulation model for the at least one component from the plurality of simulation models based on at least one of the minimum assessment accuracy and the maximum assessment duration. Thus, a digital twin may be assembled from more complex components in situations where assessment accuracy is important and/or assessment duration is not/less important.

The at least one processor may be configured to perform the simulations on the digital twin to determine one or more network configuration parameter settings of the telecommunication network and configure the telecommunication network with the one or more network configuration parameter settings. This makes it possible to configure an operational telecommunication network with better network configuration parameter settings. These simulations may be started from the current live network configuration or, if not available, from default parameter settings, vendor recommended parameter settings, middle of the range parameter settings, or arbitrary parameter settings, for example. The operational telecommunication network may be a test network or a commercial network, for example.

The one or more network configuration parameter settings may comprise an antenna tilt setting and/or a handover threshold setting and/or a transmission power setting, for example. The digital twin of the telecommunication network may additionally or alternatively be used to evaluate the addition of a new site at some time and location, for example. In other words, it may be learned from the simulations that a new site is beneficial.

The plurality of components of the digital twin of the telecommunication network may represent, in the case of a mobile communication network, network elements in the radio, core and/or cloud domains, e.g. one or more base stations and/or one or more antennas, as well as aspects of user behavior, e.g. user mobility, device/traffic characteristics and/or the propagation environment.

The at least one processor may be configured to select a problem definition from a plurality of problem definitions, each of the plurality of problem definitions specifying one or more configuration parameters to be optimized and one or more corresponding performance indicators, select the simulation model for each of the plurality of components of the digital twin further based on the selected problem definition, and select one or more configuration parameters for the simulations from the selected problem definition. The problem definition may further specify a geographical scope and/or a technological scope. The selected problem definition may include the minimum assessment accuracy and/or the maximum assessment duration.

In this way, the optimal number of components and/or the optimal degree of complexity of the components' simulation models for the digital twin may be selected for a particular problem. This solves the problem of conventional ‘one size fits all’ solutions in which a given digital twin may be modelled in too much detail and hence yield unacceptably slow simulations for one problem or be modelled in insufficient detail to yield simulations with sufficient accuracy for another problem.

The defined problem may be an optimization problem or an evaluation problem. For example, the objective of an optimization problem could be to optimize a configuration parameter (e.g. a tilt setting) in a mobile communication network, whereas the goal of an evaluation problem could be to evaluate the performance of a vendor-implemented feature in a mobile communication network with different settings of a configuration parameter. Feature assessment inherently also involves optimization of the configuration parameter in order to quantify the feature's merit (i.e. the maximum attainable performance gain, assuming optimized configuration).

In e.g. an optimization problem, the problem may be to optimize a configuration parameter with respect to a single performance indicator or with respect to multiple performance indicators (e.g. a weighted average). The performance indicator may be a composite of multiple performance indicators. The optimization of the configuration parameter may be performed under a constraint, e.g. under the same constraints used for selecting the simulation models. For example, when the simulation models were selected for each of the plurality of components based on the minimum assessment accuracy, the optimization algorithm may use the same minimum assessment accuracy as constraint.

The at least one processor may be configured to assemble simulation models into different digital twin candidates, perform multiple simulations on each of the assembled different digital twin candidates to determine training samples, generate, for a plurality of digital twin candidates, based on the training samples, a utility function with respect to the one or more performance indicators, the plurality of digital twin candidates including the assembled different digital twin candidates, generate, for the plurality of digital twin candidates, a cost function based on the training samples, and select the simulation model for each of the plurality of components of the digital twin by applying the utility function to the minimum assessment accuracy and/or by applying the cost function to the maximum assessment duration. This is an advantageous way to select the simulation model for each of the plurality of components of the digital twin based on at least one of the minimum assessment accuracy and the maximum assessment duration.

The utility function is also referred to as accuracy function. The cost function reflects the assessment effort, e.g. the number of evaluations needed to determine optimal/optimized settings of a configuration parameter multiplied with the computation time needed to evaluate a single configuration of the digital twin. The computation time needed to evaluate a single configuration is determined/learned for the system that performs the simulations. The utility and cost functions may be generated based on the training samples by using AI/ML techniques, for example.

In the case of e.g. an optimization problem, the optimization problem may be solved for each of a plurality of initial settings of the configuration parameter per digital twin candidate, e.g. to determine how many simulations/iterations need to be performed for each initial configuration in order to arrive at the optimal/optimized configuration. These initial configuration parameter settings may be selected based on expert knowledge, for example. By using AI/ML techniques, the utility function and the cost function may generated without having data on each possible (initial) setting of the configuration parameter.

It may not be feasible to perform the multiple simulations on each digital twin candidate that could be assembled. The digital twin candidates from which training samples are obtained may therefore be selected, based on expert knowledge, from a reduced collection of all possible digital twins that could be assembled. This expert knowledge may relate to the (domain of the) selected problem and/or to the used AI/ML techniques.

Expert knowledge may also be used at a later stage. The at least one processor may be configured to select the simulation model for each of the plurality of components by selecting a digital twin candidate from a plurality of digital twin candidates based on at least one of the (required) minimum assessment accuracy and the maximum (acceptable) assessment duration and further based on expert knowledge. This may help select the optimal digital twin candidate for the problem at hand in view of the constraints.

In other words, the digital twin may be selected, based on expert knowledge, from a reduced collection of all possible digital twins that could be assembled. This expert knowledge may relate to the (domain of the) selected problem and may be the same as expert knowledge that was used for selecting digital twin candidates or may be (partly) different. Selecting the simulation model for each component of the digital twin may comprise selecting one of the digital twin candidates for which training samples were obtained, but this is not required. For example, utility and cost function values may also be determined for digital twin candidates on which no simulations have been performed, e.g. by using AI/ML techniques.

The above-mentioned training samples may include values of the one or more performance indicators and the at least one processor may be configured to generate the cost function and/or the utility function based on the values of the one or more performance indicators. For example, the values of the performance indicators obtained for a certain digital twin candidate may be compared to the values of the performance indicators obtained for the most accurate digital twin candidate in order to generate the utility function.

The at least one processor may be configured to select the simulation model for each of the plurality of components of the digital twin based on the maximum (acceptable) assessment duration such that the simulations on the digital twin will have a maximized assessment accuracy without exceeding the maximum (acceptable) assessment duration. This is beneficial if it is sufficient not to exceed the maximum (acceptable) assessment duration, but it is not necessary to get the shortest assessment duration; it is more important to get the highest assessment accuracy under the assessment duration constraint. This is a tradeoff between assessment duration and assessment accuracy.

Alternatively, the at least one processor may be configured to select the simulation model for each of the plurality of components of the digital twin based on the (required) minimum assessment accuracy such that the simulations on the digital twin will have a minimized assessment duration while satisfying the (required) minimum assessment accuracy. This is beneficial if it is sufficient to satisfy the (required) minimum assessment accuracy, but it is not necessary to get the highest assessment accuracy; it is more important to get the shorted assessment duration under the assessment accuracy constraint. This is another tradeoff between assessment duration and assessment accuracy.

In a second aspect of the invention, a system for generating utility and cost functions for digital twin candidates of a telecommunication network includes at least one processor configured to assemble simulation models into different digital twin candidates of a telecommunication network, perform multiple simulations on each of the assembled different digital twin candidates to determine training samples, generate, for a plurality of digital twin candidates, based on the training samples, a utility function with respect to one or more performance indicators, the plurality of digital twin candidates including the assembled different digital twin candidates, generate, for the plurality of digital twin candidates, a cost function based on the training samples, and store in a memory information specifying the cost and utility functions generated for the plurality of digital twin candidates.

In a third aspect of the invention, a computer-implemented method of performing simulations on a digital twin of a telecommunication network comprises determining a minimum assessment accuracy with respect to one or more performance indicators and/or determining a maximum assessment duration, selecting a simulation model for each of a plurality of components of the digital twin based on at least one of the minimum assessment accuracy and the maximum assessment duration, assembling the selected simulation models into the digital twin, and performing the simulations on the digital twin. Said method may be performed by software running on a programmable device. This software may be provided as a computer program product.

In a fourth aspect of the invention, a computer-implemented method of generating utility and cost functions for digital twin candidates of a telecommunication network comprises assembling simulation models into different digital twin candidates of a telecommunication network, performing multiple simulations on each of the assembled different digital twin candidates to determine training samples, generating, for a plurality of digital twin candidates, based on the training samples, a utility function with respect to one or more performance indicators, the plurality of digital twin candidates including the assembled different digital twin candidates, generating, for the plurality of digital twin candidates, a cost function based on the training samples, and storing, in a memory, information specifying the cost and utility functions generated for the plurality of digital twin candidates. Said method may be performed by software running on a programmable device. This software may be provided as a computer program product.

Moreover, a computer program for carrying out the methods described herein, as well as a non-transitory computer readable storage-medium storing the computer program are provided. A computer program may, for example, be downloaded by or uploaded to an existing device or be stored upon manufacturing of these systems.

A non-transitory computer-readable storage medium stores at least a first software code portion, the first software code portion, when executed or processed by a computer, being configured to perform executable operations for performing simulations on a digital twin of a telecommunication network.

The executable operations comprise determining a minimum assessment accuracy with respect to one or more performance indicators and/or determining a maximum assessment duration, selecting a simulation model for each of a plurality of components of the digital twin based on at least one of the minimum assessment accuracy and the maximum assessment duration, assembling the selected simulation models into the digital twin, and performing the simulations on the digital twin.

A non-transitory computer-readable storage medium stores at least a second software code portion, the second software code portion, when executed or processed by a computer, being configured to perform executable operations for generating utility and cost functions for digital twin candidates of a telecommunication network.

The executable operations comprise assembling simulation models into different digital twin candidates of a telecommunication network, performing multiple simulations on each of the assembled different digital twin candidates to determine training samples, generating, for a plurality of digital twin candidates, based on the training samples, a utility function with respect to one or more performance indicators, the plurality of digital twin candidates including the assembled different digital twin candidates, generating, for the plurality of digital twin candidates, a cost function based on the training samples, and storing, in a memory, information specifying the cost and utility functions generated for the plurality of digital twin candidates.

As will be appreciated by one skilled in the art, aspects of the present invention may be embodied as a device, a method or a computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit”, “module” or “system.” Functions described in this disclosure may be implemented as an algorithm executed by a processor/microprocessor of a computer. Furthermore, aspects of the present invention may take the form of a computer program product embodied in one or more computer readable medium(s) having computer readable program code embodied, e.g., stored, thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples of a computer readable storage medium may include, but are not limited to, the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of the present invention, a computer readable storage medium may be any tangible medium that can contain, or store, a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber, cable, RF, etc., or any suitable combination of the foregoing. Computer program code for carrying out operations for aspects of the present invention may be written in any combination of one or more programming languages, including an object oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems), and computer program products according to embodiments of the present invention. It will be understood that each block of the flowchart illustrations and/or block diagrams, and combinations of blocks in the flowchart illustrations and/or block diagrams, can be implemented by computer program instructions. These computer program instructions may be provided to a processor, in particular a microprocessor or a central processing unit (CPU), of a general purpose computer, special purpose computer, or other programmable data processing apparatus to produce a machine, such that the instructions, which execute via the processor of the computer, other programmable data processing apparatus, or other devices create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the figures illustrate the architecture, functionality, and operation of possible implementations of devices, methods and computer program products according to various embodiments of the present invention. In this regard, each block in the flowchart or block diagrams may represent a module, segment, or portion of code, which comprises one or more executable instructions for implementing the specified logical function(s).

It should also be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

### BRIEF DESCRIPTION OF THE DRAWINGS

These and other aspects of the invention are apparent from and will be further elucidated, by way of example, with reference to the drawings, in which:

FIG. 1 is a flow diagram of a first embodiment of the method of performing simulations;

FIG. 2 is a flow diagram of a second embodiment of the method of performing simulations;

FIG. 3 is a flow diagram of a third embodiment of the method of performing simulations;

FIG. 4 illustrates a digital twin being assembled in the method of FIG. 3

FIG. 5 shows different phases which may be distinguished with respect to the steps of the methods;

FIG. 6 shows a flow diagram of an embodiment of the method of generating cost and utility functions and a fourth embodiment of the method of performing simulations;

FIGS. 7 and 8 show two example uses of example cost and utility functions;

FIG. 9 is a block diagram of embodiments of the systems; and

FIG. 10 is a block diagram of an exemplary data processing system for performing the methods of the invention.

Corresponding elements in the drawings are denoted by the same reference numeral.

### DETAILED DESCRIPTION OF THE DRAWINGS

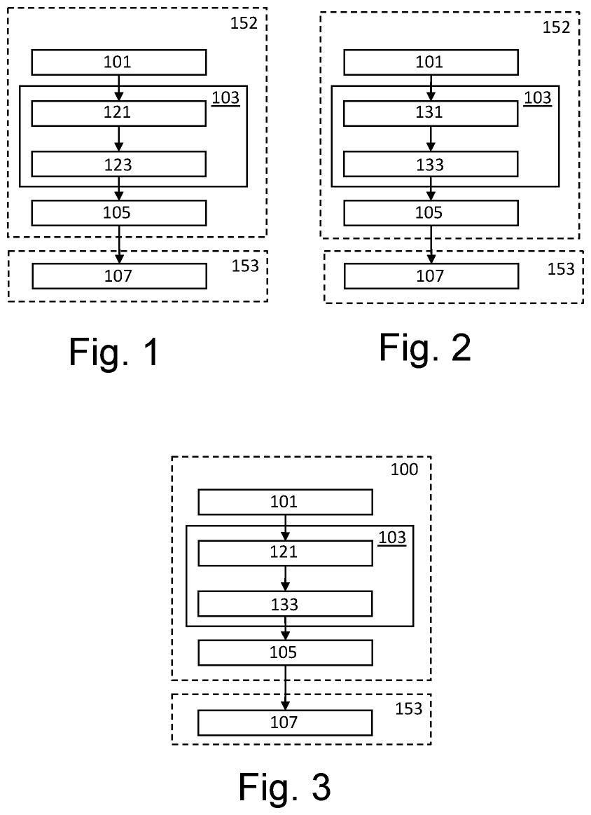

A first embodiment of the computer-implemented method of performing simulations on a digital twin of a telecommunication network is shown in FIG. 1. A step 101 comprises at least one of a) determining a (required) minimum assessment accuracy with respect to one or more performance indicators and b) determining an (acceptable) maximum assessment duration. A step 103 comprises selecting a simulation model for each of a plurality of components of the digital twin based on at least one of the minimum assessment accuracy and the maximum assessment duration, as determined in step 101. A step 105 comprises assembling the simulation models selected in step 103 into the digital twin.

A step 107 comprises performing the simulations on the digital twin assembled in step 105. The simulations may be performed to find one or more optimal configuration parameter settings, for example. A gradient-based optimization strategy may be used, for example. The simulation models may be black boxes of which certain parameter settings may be set/adjusted, for example.

Steps 101, 103, and 105 are part of an assembly phase 152 of the digital twin and step 107 is part of an exploitation phase 153 of the digital twin. According to certain definitions of the term digital twin, a digital twin is updated based on real-time data. In the context of this specification, this is possible but not required.

In the embodiment of FIG. 1, step 103 is implemented by steps 121 and 123. Step 121 comprises determining a quantity of the plurality of components based on at least one of the minimum assessment accuracy and the maximum assessment duration. In the embodiment of FIG. 1, the quantity of the plurality of components is determined in step 121 by determining a quantity of components per component type. Optionally, one or more (but not all in this embodiment) components types have a fixed quantity of components. The quantity of components per remaining component type is determined (jointly) based on at least one of the minimum assessment accuracy and the maximum assessment duration. Step 121 may comprise summing the quantities of components per component type, but this is not required.

Step 123 comprises selecting a simulation model for each of the plurality of components. In the embodiment of FIG. 1, each component type is associated with a single simulation model. As a result, the same simulation model is selected for each component with the same component type. As an example, a digital twin of a radio access network may use the component types A) base station, B) antenna, C) propagation environment, and D) user mobility. If two components of type A, four components of type B, one component of type C, and one component of type D have been determined in step 121, then eight simulation models are selected in step 123, of which the two simulation models of type A are the same and the four simulation models of type B are the same.

A second embodiment of the computer-implemented method of performing simulations on a digital twin of a telecommunication network is shown in FIG. 2. The method of FIG. 2 also comprises steps 101, 105, and 107, like the method of FIG. 1. However, in the embodiment of FIG. 2, step 103 is implemented by steps 131 and 133 and for at least one of the plurality of components, a component type of the respective component is associated with a plurality of simulation models of different degrees of complexity.

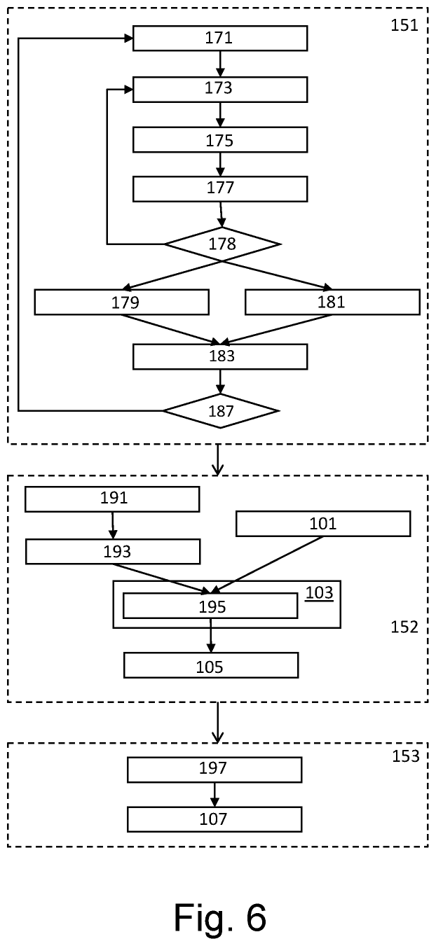

Step 131 comprises determining a quantity of the plurality of components. In the embodiment of FIG. 2, a fixed quantity of components, i.e. a quantity of components that does not depend on the minimum assessment accuracy or the maximum assessment duration, is determined for all component types. The quantity of components might still depend on the selected problem definition, as will be described in relation to FIG. 6. In a variation on the embodiment of FIG. 2, step 131 is omitted.

Step 133 comprises (jointly) selecting, based on the minimum assessment accuracy and/or the maximum assessment duration, a simulation model for each of the components that has a component type that is associated with multiple simulation models. Step 133 further comprises selecting a simulation model for each of the components that has a component type that is associated with only one simulation model, if such a component type exists. If the same simulation model is selected for each component of the same component type, then step 131 may alternatively be performed after step 133 or in parallel with step 133.

A third embodiment of the computer-implemented method of performing simulations on a digital twin of a telecommunication network is shown in FIG. 3. The method of FIG. 3 also comprise steps 101, 105, and 107, like the methods of FIGS. 1 and 2. However, in the embodiment of FIG. 3, step 103 is implemented by step 121 of FIG. 1 and step 133 of FIG. 2.

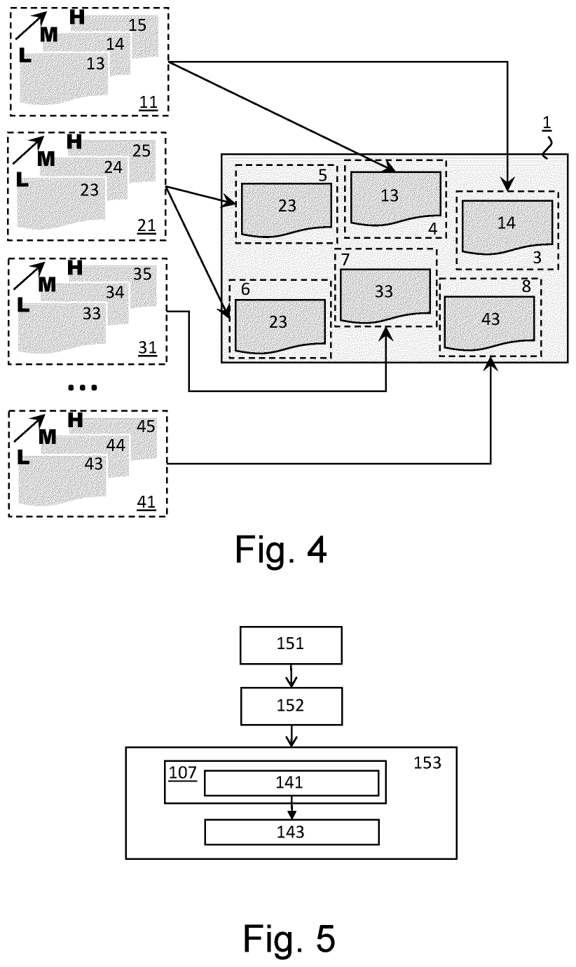

FIG. 4 illustrates a digital twin being assembled in the method of FIG. 3. FIG. 4 shows four component types 11, 21, 31, and 41. In the example of FIG. 4, each of the component types is associated with three different simulation models with different degrees of complexity (low, medium, and high). These simulation models are stored in a repository of simulation models of digital twin component types with well-defined inter-component interfaces to support tailored assembly. The digital twin of FIG. 4 is just an example: e.g. there may be more or less than four component types and/or more or less than three degrees of complexity.

Component type 11 is associated with a low-complexity simulation model 13, a medium-complexity simulation model 14, and a high-complexity simulation model 15. Component type 21 is associated with a low-complexity simulation model 23, a medium-complexity simulation model 24, and a high-complexity simulation model 25. Component type 31 is associated with a low-complexity simulation model 33, a medium-complexity simulation model 34, and a high-complexity simulation model 35. Component type 41 is associated with a low-complexity simulation model 43, a medium-complexity simulation model 44, and a high-complexity simulation model 45.

In the example of FIG. 4, in step 121 of FIG. 3, two components 3 and 4 have been determined for component type 11, two components 5 and 6 have been determined for component type 21, one component 7 has been determined for component type 31, and one component 8 has been determined for component type 41. These six components 3-8 are shown as components of the digital twin 1 in FIG. 4.

In the example of FIG. 4, in step 133 of FIG. 3, simulation models with different degrees of complexity are selected for the two components 3 and 4 of component type 11, i.e. low-complexity simulation model 13 and medium-complexity simulation model 14, while the same simulation model is selected for the two components 5 and 6 of component type 21, i.e. low-complexity simulation model 23. Additionally, the low-complexity simulation model 33 is selected for the single component 7 of component type 31 and the low-complexity simulation model 43 is selected for the single component 8 of component type 41. These simulation models are shown assembled in the digital twin 1 in FIG. 4.

In the embodiments of FIGS. 1-3, the simulation models are only selected based on the minimum assessment accuracy and/or the maximum assessment duration. In an alternative embodiment, the simulation models may be selected based on expert knowledge of the problem that has arisen, as will be described in relation to FIG. 6. For example, expert knowledge may be used to determine per component type, a preferred minimum and/or maximum quantity of components and/or a preferred minimum and/or maximum degree of complexity of the simulation model. For instance, expert knowledge may specify that for a given problem the high-complexity user mobility model is needed and/or a minimum of 57 base stations are needed.

Illustrative examples of digital twin components with different degrees of complexity include:
Base station—At one extreme, an exact fully functional replica of a base station could be used (likely provided by the equipment vendor), while at the other extreme, the base station could be reduced to merely a combination of few key radio resource management mechanisms.
Antenna—In case the addressed problem concerns the optimization of beamforming parameters, a detailed model of a deployed antenna array, including amongst others the number of antenna elements, the subarray structure and the element-level antenna diagram, may be needed, while for other problems it may suffice to reduce the antenna array to just a single effective transmit/receive antenna with a suitably configured antenna diagram.
Propagation environment—For a problem involving beamforming or channel-adaptive packet scheduling, it is important to adequately incorporate multipath fading into the propagation model, while for other problems it may suffice to exclude multipath fading altogether and model only path loss and perhaps shadow fading.
User mobility—When optimizing handover or dynamic beam steering parameters, it may be important to consider a detailed user-level mobility model. In other problems, it may be good enough to have e.g. a macroscopic model for traffic flows between industrial and residential areas, while in yet other problems, user mobility may be disregarded entirely.

Other examples include the user equipment, spatio-temporal traffic characteristics and various core network functions and interfaces.

As described in relation to FIG. 1, FIG. 1 shows an assembly phase 152 of the digital twin and an exploitation phase 153 of the digital twin. FIG. 5 further shows a preparatory phase 151 before the assembly phase 152. While the assembly phase 152 and the exploitations phase 153 are online phases, the preparatory phase 151 is normally an offline phase. The preparatory phase 151 covers the development of the simulation models of the component types of the digital twin of the telecommunication network in question, possibly involving measurements done upon the telecommunication network and AI/ML methodologies in the modelling itself. In an embodiment, the preparatory phase 151 is also responsible for generating various utility or cost functions (e.g. related to assessment accuracy and assessment duration), see e.g. FIG. 6.

As, depending on the context, the telecommunication network may undergo continuous changes, the preparatory phase 151 may be a continuous process of developing/tuning the simulations models of the component types. The assembly phase 152 deals with the tailored assembly of the digital twin by selecting relevant models built in the preparatory phase 151. In the exploitation phase 153, the assembled digital twin is utilized in simulation, e.g. in order to assess the impact of candidate configurations/actions and effectuate a selected configuration/action upon the twinned telecommunication network.

In the embodiments of FIGS. 1-3, the exploitation phase 153 comprises a step 107. Step 107 comprises performing the simulations on the digital twin assembled in step 105. In a variation on the embodiments of FIGS. 1-3, step 107 is implemented by a step 141 and the exploitation phase 153 further comprises a step 143. This is shown in FIG. 5.

Step 141 comprises performing the simulations on the digital twin assembled in step 105 to determine one or more network configuration parameter settings of the telecommunication network. Examples of configuration parameters for the radio access network of a mobile communication network are handover thresholds, scheduling weights, admission control thresholds, congestion control parameters, massive MIMO/beamforming parameters, CSI feedback configuration parameters, and slicing parameters. Examples of configuration parameters for the core network of a mobile communication network are slicing parameters, routing policy parameters, QoS management parameters, charging policy parameters, service area restriction parameters, PLMN selection parameters, and paging policy parameters. Step 143 comprises configuring the twinned telecommunication network with the one or more network configuration settings determined in step 141.

An embodiment of the computer-implemented method of generating cost and utility functions and a fourth embodiment of the computer-implemented method of performing simulations on a digital twin of a telecommunication network are shown in FIG. 6. The method of generating cost and utility functions is performed in the preparatory phase 151. The method of performing simulations on the digital twin comprising steps 101-107 is performed in the assembly phase 152 and the exploitation phase 153.

As previously explained, the preparatory phase 151 covers the development of the simulation models of the component types of the digital twin of the telecommunication network in question, possibly involving measurements done upon the telecommunication network and the application of AI/ML methodologies in the modelling itself. This may be performed with conventional techniques. The availability of a repository of simulation models of digital twin component types with well-defined inter-component interfaces to support assembly is assumed.

The preparatory phase 151 comprises steps 171, 173, 175, 177, 178, 179, 181, 183, and 187. In a first iteration of step 171, step 171 comprises selecting a first problem definition from a plurality of problem definitions. Each of the plurality of problem definitions specifies one or more configuration parameters to be optimized and one or more corresponding performance indicators. One or more performance indicators for which a minimum value and/or a maximum value needs to be achieved may optionally be included in the problem definition (as constraints). Examples of performance indicators are throughput and latency.

Examples of configuration parameters have been described in relation to FIG. 5. The problem definition may further specify a geographical scope and/or a technological scope. The problem definition may further specify the (required) minimum assessment accuracy and/or the (acceptable) maximum assessment duration, but if not, this may be input separately in the assembly phase 152.

The problem definition may specify an optimization or an evaluation problem, for example. In both cases, the simulations are performed to find one or more optimal/optimized configuration parameter settings with respect to the performance indicators (typically with certain constraints). The goal of solving the optimization problem is to find the one or more optimal/optimized configuration parameter settings. The goal of solving the evaluation problem is to find the values of the performance indicators corresponding to these one or more optimal/optimized configuration parameter settings.

In the assembly phase 152, a problem may be periodically triggered as part of an automated network optimization loop, or be triggered by incidental events such as the failure of a base station or by a network engineer activating the evaluation of a vendor-implemented feature in a mobile operator's network. When a problem arises in the assembly phase 152, the corresponding problem definition is selected from the plurality of problem definitions, e.g. from a list of problem definitions.

With respect to the targeted performance indicators, a well-defined optimization/evaluation problem should preferably include a clear definition of what needs to be optimized/evaluated, which could e.g. simply be a single KPI (e.g. the coverage probability), a weighted average of multiple KPIs (K_{X}, K_{Y}), i.e. K=α_{X} K_{X}+β_{Y} K_{Y}, (e.g. 0.8×the dropping probability+0.2×the handover ping-pong ratio), or a combination of an optimization KPI and a conditional KPI, i.e. K=K_{X}×1(K_{Y}>=K_{YMIN}), where 1( ) refers to the indicator function (e.g. optimize average user throughput under the condition that the coverage probability exceeds 99%). The term “one or more performance indicators” covers all these options.

In a first iteration of step 173, step 173 comprises selecting a simulation model for each of a plurality of components of a first candidate digital twin. Step 173 may be similar to step 103 of FIGS. 1-3. Thus, a desired quantity of components may be determined in step 173 (e.g. per component type) and/or simulation models with a desired degree of complexity may be determined in step 173 (e.g. per component or component type). The desired quantity of components may depend on the degree of complexity of the selected simulation models. In a first iteration of step 175, step 175 comprises assembling simulation models of the plurality of components into the first digital twin candidate. Step 175 may be similar to step 105 of FIGS. 1-3.

Each (candidate) digital twin can be represented by a vector n. The vector n indicates for each twin component type and associated complexity level available in the repository, how many components of it are included in the digital twin (e.g. n=#BSs of high complexity level, #BSs of medium complexity level, #BSs of low complexity level, #Antennas of high complexity level, #Antennas of medium complexity level, #Antennas of low complexity level, etc.). Some of these may be set to 0.

Step 177 comprises performing multiple simulations on the digital twin candidate assembled in step 175 to determine training samples. For a given problem and n, iterative simulations are conducted with various settings for the one or more configuration parameters (e.g. a range of tilt settings). The training samples typically include values of the one or more performance indicators. For a given n, step 177 may comprise the following two substages:
Determine settings for the one or more configuration parameters (e.g. a range of tilt settings to evaluate for a particular problem). Expert knowledge may be used to select the settings for the one or more configuration parameters, i.e. to select the candidate configurations. This substage may include selecting initial configurations.
Conduct actual simulations for the given n and candidate configurations. Different runs are performed for different n. Each run comprises multiple iterations. (Pseudo-) random values may be used in the simulations. For this reason, a sufficient number of independent replications with distinct random seeds is preferably conducted as part of each iteration to achieve the required statistical accuracy on the performance indicator(s). Distinct sets of replications may be performed for one or more load levels/scenarios. One or more runs are performed starting from one or more different initial configurations. In each run, iterations of the optimization algorithm are performed until the stopping criterion of the optimization algorithm is met. After an iteration with an initial configuration and after each next iteration, the optimization algorithm determines which next configuration to try. After the stopping criterion of the optimization algorithm is met, the total time (number of simulations/iterations multiplied with average time per simulation/iteration) needed to determine the optimized configuration and the corresponding estimates (which are deemed statistically reliable) of the performance indicators are stored/output in relation to the given n. If multiple runs are performed starting from multiple different initial configurations, the average total time per run may be stored/output in relation to the given n. The individual output of this substage may be used as training samples (e.g. [problem, n, KPI name]->[KPI value, total time]) to learn the cost and utility functions. If the optimized configuration is on the edge of a range of candidate configurations, the range may be adjusted to cover candidate configuration beyond this edge. In this case, the first substage and the second substage may be repeated and other candidate/initial configurations may be selected in the first substage. An example of an optimization algorithm that may be used is gradient-based optimization in multidimensional space. The individual simulation models per component type are typically black boxes.

A step 178 comprises checking whether simulations need to be performed on a further digital twin candidate, i.e., whether simulations have been performed on a sufficient number of digital twin candidates. Expert knowledge is preferably used to limit the set of digital twin candidates from which digital twin candidates are selected in step 173. In this case, step 178 may comprise checking whether a sufficient number of digital twin candidates has been selected from this set to generate suitable cost and utility functions with a reasonable amount of effort.

If simulations need to be performed on a further digital twin candidate, step 173 is repeated and the method proceeds as shown in FIG. 6. In a next iteration of step 173, step 173 comprises selecting a simulation model for each of a plurality of components of a next candidate digital twin. In a next iteration of step 175, step 175 comprises assembling simulation models of the plurality of components into the next digital twin candidate.

Step 179 and 181 are performed after step 178. Step 179 comprises generating, for a plurality of digital twin candidates, based on the training samples determined in step 177, a utility function with respect to the one or more performance indicators. The plurality of digital twin candidates includes each digital twin candidate assembled in step 175. The utility function reflects estimated accuracy with respect to the one or more performance indicators. Step 181 comprises generating, for the plurality of digital twin candidates, a cost function based on the training samples determined in step 177. The cost function reflects experienced, and optionally estimated, assessment effort. Steps 179 and 181 may involve the use of machine learning techniques, e.g., for estimating assessment duration and accuracy for candidate twins for which no training samples have been obtained. In an alternative embodiment, only the utility function is generated or only the cost function is generated.

Typically, the utility function is determined based on values of the one or more performance indicators included in the training samples. For example, the utility function may be generated by first determining the digital twin candidate with the digital twin candidate yielding the most accurate performance result, i.e. the full-swing digital twin. The full-swing digital twin considers for each component type the most complex simulation model available and considers the entire network or a subset thereof that yields the same assessment accuracy. The utility function may be determined through normalization such that the function result is 1 for this digital twin candidate and between 0 and 1 for the other digital twin candidates. The utility function result value for a certain digital twin candidate reflects the utility of this digital twin candidate relative to the digital twin candidate with the highest utility (i.e. result value 1).

The cost function may be generated, for example, by determining, for each digital twin candidate, the average or maximum total time needed to determine the optimal/optimized configuration (e.g. average or maximum of multiple iterations of the optimization algorithm with different initial configurations) or by determining, for each digital twin candidate, the average or maximum number of simulations/iterations needed to determine the optimized configuration and multiplying this average or maximum number of simulations/iterations with the computational time (e.g. in seconds) needed to perform a single simulation/iteration.

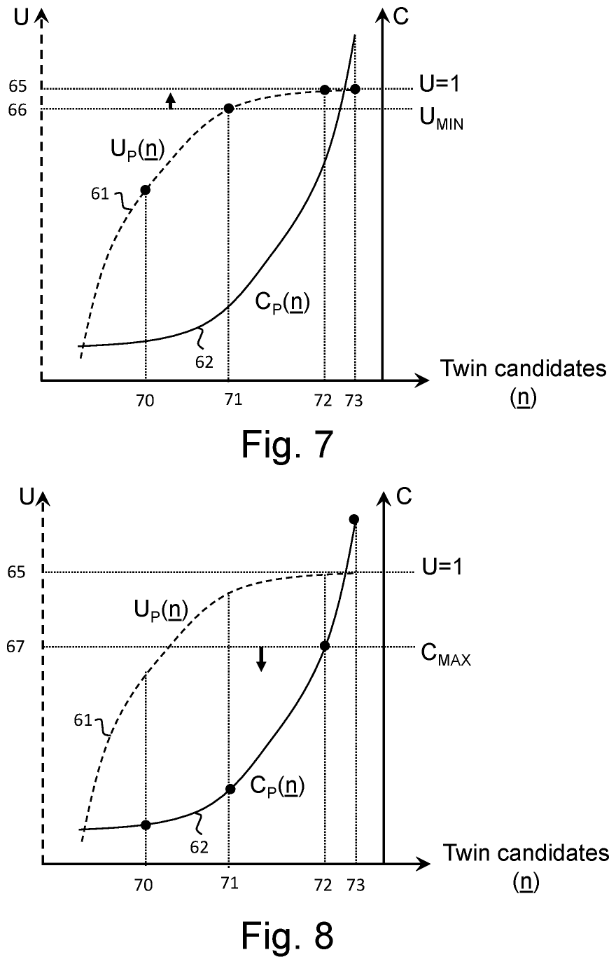

For each considered configuration, sufficient replications with distinct random seeds are preferably performed to obtain sufficient statistical reliability of the obtained performance results. Thus, each iteration may comprise one or more replications. Examples of a utility function and a cost function are shown in FIGS. 7 and 8. A step 183 comprises storing in a memory, information specifying the cost and utility functions generated for the problem definition selected in step 171.

A step 187 comprises checking whether cost and utility functions should be generated for a further problem definition. If steps 173-183 have been performed for all of the plurality of problem definitions, then the preparatory phase 151 has been completed (although it may be repeated later). If steps 173-183 have not been performed for all of the plurality of problem definitions, step 171 is repeated, and the method proceeds as shown in FIG. 6. In a next iteration of step 171, step 171 comprises selecting a next problem definition from the plurality of problem definitions.

Machine learning may be used to determine cost function result values and utility function result values that relate to digital twin candidates for which no simulations have been performed. It may even be possible to use training samples obtained for one problem to learn the cost and utility functions for another problem. In that case, steps 179, 181, and 183 may be performed after step 187 instead of before step 187. In any case, the cost and utility functions are generated for each problem from the plurality, e.g. list, of potential problems.

As explained above, the assembly phase 152 deals with the tailored assembly of the digital twin by selecting relevant models built in the preparatory phase 151. In the embodiment of FIG. 6, relevant utility and cost functions are selected in the assembly phase 152 to determine a digital twin when an actual problem arises.

The assembly phase 152 comprises steps 191, 193, 195, 101, 103, and 105. Step 191 comprises selecting a problem definition from the plurality of problem definitions. In the assembly phase 152, the selected problem definition needs to correspond to the problem that has arisen in the operational telecommunication network. Thus, if the problem definition is not selected fully automatically by the system but is selected based on user input, the user should not select any problem definition that does not correspond to the problem that has arisen. The operational telecommunication network may be a test network or a commercial network, for example. Step 193 comprises retrieving from the memory the cost and utility functions generated associated with the problem definition selected in step 191.

Step 101 comprises determining a (required) minimum assessment accuracy with respect to the one or more performance indicators specified in the selected problem definition and/or determining an (acceptable) maximum assessment duration. In the embodiment of FIG. 6, the minimum assessment accuracy and/or maximum assessment duration are determined separately in step 101 and are not specified in the problem definition. In an alternative embodiment, the problem definition includes the (required) minimum assessment accuracy and/or the (acceptable) maximum assessment duration.

Step 103 is performed after steps 193 and 101 have been performed. Step 103 is implemented by a step 195. Step 195 comprises selecting a simulation model for each of the plurality of components of a digital twin by performing at least one of: a) applying the utility function corresponding to the problem definition, retrieved in step 193, to the minimum assessment accuracy determined in step 101 and b) applying the cost function corresponding to the problem definition, retrieved in step 193, to the maximum assessment duration determined in step 101. Step 195 may be viewed as a step which comprises selecting a digital twin from a plurality of digital twin candidates based on at least one of the minimum assessment accuracy and the maximum assessment duration and further based on the selected problem definition.

Digital twin candidates may differ from each other by having a different quantity of components and/or by having simulation models of different degrees of complexity, as described in relation to FIGS. 1-3. Step 195 may comprise a first sub step in which a subset of the plurality of digital twin candidates is selected and a second sub step in which the digital twin is selected from the subset. This subset may be selected based on expert knowledge, for example. For example, for a tilt optimization problem, it is fine to only consider low complexity BSs. Information facilitating the selection of the subset (and representing the expert knowledge) may be included in the problem definition, for example.

The plurality of digital twin candidates may comprise all possible digital twin candidates and may even be infinite. In this case, the plurality of digital twin candidates may comprise digital twin candidates for which no training samples were obtained in step 177 but for which utility and cost values can be derived/learned from the utility and cost values determined for the other digital twin candidates. Alternatively, the plurality of digital twin candidates may comprise only digital twin candidates for which training samples were obtained in step 177.

As mentioned above, selection of the optimal degree of complexity and/or the optimal number of components per component type is important for tailoring the digital twin and this selection can be made based on the minimum assessment accuracy and/or the maximum assessment duration.

The actual assessment duration normally depends on the available computational resources. Since higher degrees of complexity require more computational resources in terms of e.g. processing capacity or memory resources, the availability of such resources may also affect the feasibility of solving a given optimization problem within a given deadline and for a given degree of twin complexity. Consequently, a limitation in the computational resources may impose a limitation in the allowed degree of complexity. It may be assumed that exploitation phase 153 is performed using the same computational resources as preparatory phase 151 and that the cost functions can therefore be used without adjustment, or that it is known how to convert the times to the actual computational resources.

The (acceptable) maximum assessment duration normally depends on the urgency of the optimization problem. For instance, in case a site fails and surrounding sites need to reconfigure their antenna tilts or power settings, it may be fine to find a suboptimal solution as long as it is found fast (quick-and-dirty), hence allowing a low degree of twin complexity. Alternatively, the process of periodically updating antenna tilts and power settings in response to tempo-spatial changes in the offered traffic load, does not require urgent solutions and hence can utilize more complex twins to achieve a solution which is (close to) optimal.

A tradeoff may need to be made between the quantity of components selected per component type and the complexity of the components selected per component type. This tradeoff normally depends on the scope of the optimization problem and may be made with the help of expert knowledge. Some optimization problems are inherently geographically local in nature, e.g. the cell-specific configuration of packet scheduling parameters. Consequently, twin-based experimentations to derive the optimal parameter settings can be done for a single-cell scenario which allows a twin with much detail to be used and still be doable within reasonable time. Alternatively, the aforementioned antenna tilt optimization problem inherently requires a broader (regional) scope, as the tilt settings affect inter-cell interference and jointly determine coverage. Consequently, the degree of twin complexity should be lower than in the previous (local) optimization example, to allow a wide range of per-antenna tilt settings to be evaluated within reasonable time.

Besides having a limited geographical scope, a problem may also be characterized by having a limited technological/network scope, e.g. involving only the RAN or a more elaborate RAN/CN scope, or involving only a limited set of protocol layers. As with a limited geographical scope, also here the scope may impact the modelling extent and consequently the degree of twin detail that is needed.

Step 105 comprises assembling the simulation models selected in step 103 (e.g., for the quantity of components determined in step 103 and/or with the degrees of complexity determined in step 103), i.e. the simulation models associated with the digital twin selected from the plurality of digital twin candidates, to obtain the digital twin. In the embodiment of FIG. 6, the digital twin candidates assembled in step 175 are not stored in a memory. In an alternative embodiment, if the digital twin selected from the plurality of digital twin candidates has already been assembled, e.g. in step 175, and stored in memory, the selected digital twin may be obtained from the memory.

Next, the tailored digital twin assembled in the assembly phase 152 is applied in the exploitation phase 153 in a set of problem-specific simulations in order to derive one or more optimal/optimized configuration parameter settings (e.g. tilt setting) that may subsequently be applied in the operational telecommunication network, e.g. test telecommunication network or commercial telecommunication network.

The exploitation phase 153 comprises steps 197 and 107. Step 197 comprises selecting the one or more configuration parameters specified in the problem definition selected in step 191. Step 107 comprises performing the simulations on the digital twin assembled in step 105 with different settings of the one or more configuration parameters selected in step 197, e.g. starting from the current live network configuration or, if not available, from default parameter settings, vendor recommended parameter settings, middle of the range parameter settings, or arbitrary parameter settings.

The simulations performed in step 107 are similar to the simulations performed in step 177 but only for one problem and one assembled digital twin, i.e. the selected digital twin candidate. If the (acceptable) maximum duration allows, the simulations may be performed using multiple initial configurations. For example, insights obtained from a given set of simulations with one or more initial configurations may suggest a new initial configuration. The optimization algorithm and the stopping criterion used in step 177 may also be used in step 107. As mentioned above, an example of an optimization algorithm that may be used is gradient-based optimization in multidimensional space. Optionally, step 107 is implemented by step 141 and step 107 is followed by step 143, as described in relation to FIG. 5.

FIGS. 7 and 8 show two example uses of example cost and utility functions. Although there may be situations when only the cost function or only the utility function is needed, typically, the selection of the digital twin from the plurality of digital twin candidates involves a trade-off between the accuracy of the outcome and the assessment effort (i.e. the time it takes to determine the optimal/optimized configuration). As described in relation to FIG. 6, based on (e.g. periodic) off-line experiments with distinct digital twin candidates, relevant utility or cost functions (e.g. related to estimated assessment accuracy and estimated assessment effort/duration), may be generated, e.g. machine-learned.

FIGS. 7 and 8 show a Utility function U_{P}(n̅) 61 and a Cost function C_{P}(n̅) 62. The Utility function U_{P}(n̅) 61, also referred to as accuracy function, expresses for each twin option, the proximity of an achieved performance for a particular problem P relative to that for a full-swing (most realistic, closest to real-world object and assumed to be the ground truth) model of the twin. Hence, this curve 61 converges to ‘1’, as the considered twin option becomes as complex as the full-swing twin and in fact, depending on the addressed problem, may reach the ‘1’ level for twin candidates less complex than the full-swing model. The full-swing digital twin 73 considers for each component type the most complex component model available with a sufficiently high number of components. Ideally, the full-swing digital twin 73 should consider the entire network. However, in practice, a subset of the entire network may be sufficient.

The Cost function C_{P}(n̅) 62, also referred to as assessment effort function, indicates the assessment effort (e.g. in seconds) required to determine the configuration parameter settings that are optimal/optimized for digital twin n. Cost function C_{P}(n̅) 62 may be the multiplication of E_{P}(n̅) with T_{P}(n̅). E_{P}(n̅) is the expected number of configurations that need to be simulated to determine the optimal configuration parameter settings (e.g. the number of tilt vectors that need to be simulated as part of the optimization algorithm in order to determine the optimal/optimized configuration parameter settings, i.e. the number of iterations; this number typically increases with the number of BSs included in the twin). T_{P}(n̅) is the computational time (absolute, e.g. in seconds) needed to accurately simulate a single configuration of the digital twin given by n, i.e. the computational time of a single iteration.

As mentioned above, the functions U_{P}(n̅), E_{P}(n̅) and T_{P}(n̅) depend on the problem (P). Letting E_{P}(n̅) vary with the problem may lead to better estimates on the expected number of simulations needed because it would not be averaged over all the potential problems (e.g. the number of possible tilt settings is different than the number of possible scheduling parameter settings and optimization would therefore require different numbers of simulations/iterations). For a particular problem, U_{P}(n̅) can be obtained by observing or estimating (e.g., in case of interpolations or use of an AI/ML model) the achieved (potentially composite) one or more performance indicators and T_{P}(n̅) can be obtained by calculating the required simulation time with respect to the targeted (potentially composite) KPI.

Once a periodic or event-induced problem triggers the use of a digital twin, the most suitable twin option may be selected based on the (required) minimum assessment accuracy and (acceptable) maximum assessment duration. To find the optimal digital twin, the trade-off between the accuracy of the outcome and the assessment effort may be made in different ways. For instance, the following options may be considered:
I. maximize U_{P}(n̅) subject to C_{P}(n̅)≤C_{MAX}; or
II. minimize C_{P}(n̅) subject to U_{P}(n̅)≥U_{MIN}

As explained in relation to step 195 of FIG. 6, first a subset of a plurality of digital twin candidates may be selected based on expert knowledge and then the digital twin may be selected from the subset. This subset may be selected based on expert knowledge related to the problem, for example. For example, for a tilt optimization problem, it is fine to only consider low complexity BSs. This expert knowledge may be the same or (partly) different from the expert knowledge used in the preparatory phase 151. For example, the expert knowledge used in the preparatory phase 151 may comprise knowledge on machine learning in addition to knowledge related to the problem.

FIG. 7 illustrates option II. FIG. 7. shows that the simulation model is selected for each of the plurality of components of the digital twin based on the minimum required assessment accuracy such that the simulations on the digital twin will have a minimized assessment duration while satisfying the minimum assessment accuracy U_{MIN} represented by line 66. As explained above, the quantity of the plurality of components may be chosen as part of the selection of the simulation model for each of the plurality of components and might not be given a priori.

The digital twin candidate with the lowest assessment duration under this condition is digital twin candidate 71, which is therefore selected. The maximum assessment accuracy (i.e., 1) is represented by line 65. The full swing digital twin candidate 73 has the maximum assessment accuracy. Curve 61 increases relatively fast and relatively many digital twin candidates have an assessment accuracy of 1 or close to 1. Digital twin candidate 72 has almost the same assessment accuracy as full swing digital twin candidate 73. Although full swing digital twin candidate 73 and digital twin candidate 72 have at least the minimum assessment accuracy U_{MIN}, they do not have a minimized assessment duration. Digital twin candidate 70 does not meet the condition, as U_{P}(n̅) does not equal or exceed U_{MIN}.

FIG. 8 illustrates option I. FIG. 8 shows that the simulation model is selected for each of the plurality of components of the digital twin based on the maximum allowable assessment duration such that the simulations on the digital twin will have a maximized assessment accuracy without exceeding the maximum assessment duration C_{MAX} represented by line 67. As explained above, the quantity of the plurality of components may be chosen as part of the selection of the simulation model for each of the plurality of components and might not be given a priori.

The digital twin candidate with the highest assessment accuracy under this condition is digital twin candidate 72, which is therefore selected. Full swing digital twin candidate 73 does not meet the condition, as C_{P}(n̅) exceeds the maximum assessment duration for full swing digital twin candidate 73. Although digital twin candidates 70 and 71 meet the condition, i.e. C_{P}(n̅) does not exceed C_{MAX}, they do not have a maximized assessment accuracy.

In the examples of FIGS. 7 and 8, only the four digital twin candidates 70-73 have been addressed, but the curves 61 and 62 represent more digital twin candidates than only these four. The fact that digital twin candidates 70-73 have been addressed does not necessarily mean that training samples have been obtained for (all) these digital twin candidates in the preparation phase. Other options than options I and II are also possible. It is not required to minimize the assessment duration or maximize the assessment accuracy.

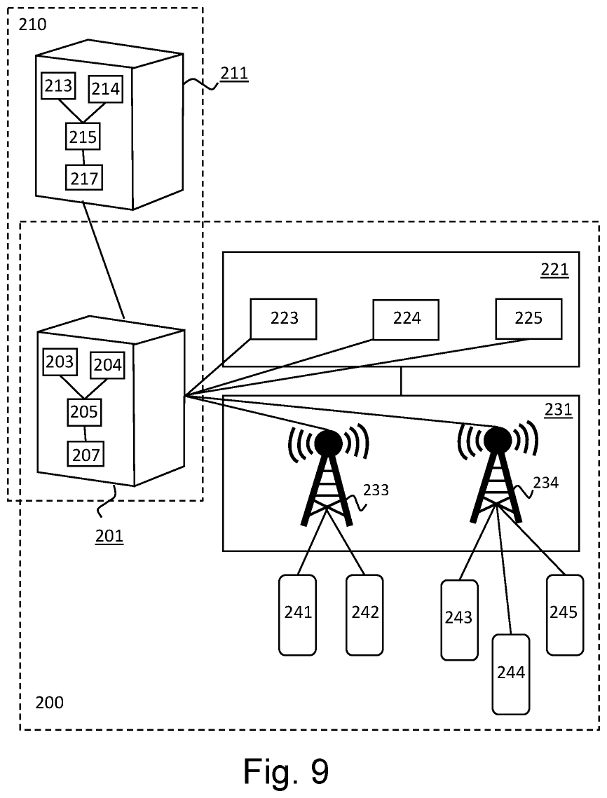

FIG. 9 is a block diagram of an embodiment of the system for performing simulations on a digital twin of a telecommunication network and an embodiment of the system for generating utility and cost functions for digital twin candidates of a telecommunication network. The system for generating the utility and cost functions comprises at least a device 211 and may further comprise device 201, for example. The system for performing simulations on a digital twin of a telecommunication network comprises at least a device 201 and may further comprise device 211, for example. A system 210 comprises both the device 201 and the device 211. In the example of FIG. 9, the telecommunication network is a mobile communication network 200. The mobile communication network 200 comprises a radio access network (RAN) 231 and a core network (CN) 221, amongst others.

The RAN 231 comprises base stations 233 and 234. The mobile communication network 200 may be a 5G network, the RAN 231 may be a 5G New Radio RAN, and the base stations 233 and 234 may be 5G gNodeB base stations, for example. Each of the base stations 233 and 234 may comprise a plurality of distributed units that share a common centralized unit in a Centralized RAN (C-RAN) architecture. The CN 221 comprises core network components 223, 224, and 225.

The device 201 is used online for managing the RAN 231 and the CN 221 and may be part of a management network of the mobile communication network 200. The device 211 is used off-line for generating the utility and cost functions. In the example of FIG. 9, mobile devices 241 and 242 are connected to base station 233 and mobile devices 243, 244, and 245 are connected to base station 234.

The device 211 comprises a receiver 213, a transmitter 214, a processor 215, and a memory 217. The processor 215 is configured to assemble simulation models of the plurality of components into different digital twin candidates of a telecommunication network, perform multiple simulations on each of the assembled different digital twin candidates to determine training samples, generate, for a plurality of digital twin candidates, based on the training samples, a utility function with respect to one or more performance indicators, the plurality of digital twin candidates including the assembled different digital twin candidates, generate, for the plurality of digital twin candidates, a cost function based on the training samples, and store in a memory information specifying the cost and utility functions generated for the plurality of digital twin candidates.

The device 201 comprises a receiver 203, a transmitter 204, a processor 205, and a memory 207. The processor 205 is configured to determine a minimum assessment accuracy with respect to one or more performance indicators and/or determine a maximum assessment duration, select a simulation model for each of a plurality of components of the digital twin based on at least one of the minimum assessment accuracy and the maximum assessment duration, assemble the selected simulation models into the digital twin, and perform the simulations on the digital twin.

If the digital twin is of the RAN 231, the base stations 233 and 234 and other base stations may be represented as components of the digital twin. Antennas of the base stations 233 and 234 and of other base stations may also be represented as components of the digital twin. User mobility and the propagation environment may also be represented as components of the digital twin. If the digital twin is of the mobile communication network 200, the core network components 223-224 may also be represented as components of the digital twin.

The processor 205 may be configured to select the simulation model for each of the plurality of components of the digital twin based on at least one of the minimum assessment accuracy and the maximum assessment duration by determining a quantity of the plurality of components based on at least one of the minimum assessment accuracy and the maximum assessment duration and selecting a simulation model for each of the plurality of components.

Additionally or alternatively, if one or more of the component types are associated with a plurality of simulation models of different degrees of complexity, the processor 205 may be configured to select the simulation model for each of the plurality of components of the digital twin based on at least one of the minimum assessment accuracy and the maximum assessment duration by (jointly) selecting the simulation model for each component of the one or more component types from the plurality of simulation models associated with the corresponding component type based on at least one of the minimum assessment accuracy and the maximum assessment duration.

In the embodiment of FIG. 9, the processor 205 is configured to select the simulation model for each of the plurality of components of the digital twin by applying a utility function generated by device 211 to the minimum assessment accuracy and/or by applying a cost function generated by device 211 to the maximum assessment duration. In an alternative embodiment, the processor 205 is configured to select the simulation model for each of the plurality of components of the digital twin in a different manner.

In the embodiment of FIG. 9, devices 201 and 211 are separate devices. In an alternative embodiment, a single device performs the functions performed by devices 201 and 211. In another embodiment, the functions performed by device 201 are performed by multiple devices and/or the functions performed by device 211 are performed by multiple devices.

In the embodiments shown in FIG. 9, the devices 201 and 211 comprise one processor 205 or 215. In an alternative embodiment, the device 201 and/or the device 211 comprises multiple processors. The processor may be a general-purpose processor, e.g., an Intel or an AMD processor, or an application-specific processor, for example. The processor may comprise multiple cores, for example. The processor may run a Unix-based or Windows operating system, for example. The memory 205 and/or the memory 215 may comprise solid state memory, e.g., one or more Solid State Disks (SSDs) made out of Flash memory, or one or more hard disks, for example.

The receivers 203 and 213 and the transmitters 204 and 214 may use one or more communication technologies (wired or wireless) to communicate with each other and with other devices, e.g. in the RAN or in the CN. The receiver and the transmitter may be combined in a transceiver. The devices 201 and 211 may comprise other components typical for a computer server or a network unit, e.g., a power supply.

In a typical example, an example optimization problem requires the assembly of a digital network twin comprising a mix of high- and low-complexity components. This example entails the periodic optimization of antenna downtilts in response to tempo-spatial changes in the offered traffic load.

In this typical example, the objective of tuning antenna downtilts is to optimize, for a given load scenario, the offered service quality under the condition that some minimum degree of (e.g. 99.5%) coverage is ensured. It is readily understood that not only the absolute load level, but also the spatial distribution of the traffic affects the optimal tilt settings. For instance, if all users are located close to the base station sites, the optimal downtilt is likely to be larger than if users are uniformly spread over the area or even if the distribution is skewed towards the cell edges. Since users tend to move over time (e.g. between working hours and off hours) and their communication needs also change over time (e.g. work-oriented emails during the day versus HD video streaming at night), it makes sense that the optimal antenna tilt settings may also change over time.

The problem definition specifies a geographical area comprising e.g. a hundred base stations, specifies the per-sector antenna downtilts as the configuration parameters, and specifies the composite KPI as formulated above: optimizing the service quality (e.g. the 10th user throughput percentile) under the condition that the coverage level exceeds e.g. 99.5%. Furthermore, the urgency level is marked low and quantified as a maximum assessment duration of up to tens of minutes. This maximum assessment duration may be included in the problem definition or specified separately. The latter is beneficial if the maximum assessment duration may vary while the (rest of the) problem definition stays the same.

In this example, the digital twin needed to suitably model the network for this optimization problem comprises simulation models for at least the deployed base station antennas, the propagation environment and the spatial traffic distribution. For each base station antenna, a rather accurate (high-complexity) simulation model is needed, realistically capturing the antenna height, azimuth direction, 3D radiation pattern and transmit power, since all of these aspects significantly affect the coverage, experienced SINR and hence service quality. A large-scale characterization of the propagation environment will likely suffice to be included in the correspondingly selected (low-complexity) simulation model, covering, amongst others, distance-based path loss, indoor penetration loss and lognormal fading aspects.

In this example, small-scale propagation aspects such as multipath fading may be excluded, since the associated small-scale variability is typically not dealt with by tuning the antenna tilt setting, but rather by e.g. adaptive modulation and coding, transmit power control and channel-adaptive packet scheduling. Lastly, an estimate of the spatial traffic distribution valid for the upcoming period is used. Since details at the user-specific level are not needed (a macroscopic accuracy up to a level of 40×40 m pixels is typically fine) and user mobility may be ignored, a medium-complexity simulation model is deemed fine for the spatial traffic distribution. It is noted that the thus assembled digital twin consciously omits various aspects that may be relevant for other optimization studies, such as a detailed modelling of various RRM mechanisms, such as packet scheduling, handover management, admission/congestion control.

The simulations involve the consideration of multiple antenna tilt tuples. In order to find the optimal antenna downtilts, an initial tuple may be selected based on the current live configuration and subsequent tuples may then intelligently selected based on e.g. a gradient-based optimization strategy. All tuples are evaluated with the selected digital twin. With the composite KPI in mind, the optimization strategy will keep track of the best tilt tuple assessed so far, which upon sufficient convergence of the approach will be selected as optimal solution and applied in the operational telecommunication network.

As described above, the simulation model may be selected on component type level or on component level. For illustrative purposes, three simulation models with distinct complexity levels may be distinguished for the component type propagation environment:
A low-complexity simulation model of the propagation environment could be as outlined above, comprising only large-scale aspects such as distance-based path loss, indoor penetration loss and lognormal fading. This model may be suitable for the periodic optimization of antenna downtilts.
A somewhat more complex simulation model (of medium complexity) could further include small-scale aspects of multipath fading, modelled as a relatively simple time/frequency-domain variation of the propagation gain around a large-scale average. This model may be used for optimizing the configuration of a packet scheduler.
A high-complexity simulation model of the propagation environment involves all of the above aspects and further includes a characterization of the small-scale propagation aspects on a per-transmit/receive antenna pair basis or even on a per path basis, which may be needed when optimizing physical layer algorithms, SU/MU-MIMO beamforming strategies and corresponding multi-user packet (co-)scheduling algorithms.

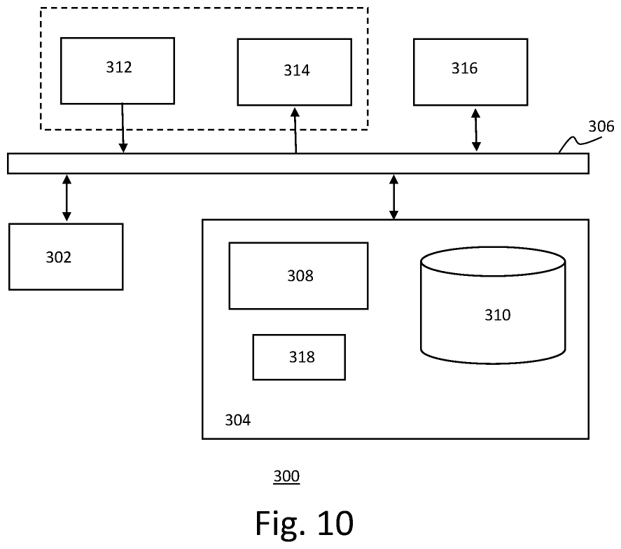

FIG. 10 depicts a block diagram illustrating an exemplary data processing system that may perform the method as described with reference to FIGS. 1-3 and 5-6.

As shown in FIG. 10, the data processing system 300 may include at least one processor 302 coupled to memory elements 304 through a system bus 306. As such, the data processing system may store program code within memory elements 304. Further, the processor 302 may execute the program code accessed from the memory elements 304 via a system bus 306. In one aspect, the data processing system may be implemented as a computer that is suitable for storing and/or executing program code. It should be appreciated, however, that the data processing system 300 may be implemented in the form of any system including a processor and a memory that is capable of performing the functions described within this specification.

The memory elements 304 may include one or more physical memory devices such as, for example, local memory 308 and one or more bulk storage devices 310. The local memory may refer to random access memory or other non-persistent memory device(s) generally used during actual execution of the program code. A bulk storage device may be implemented as a hard drive or other persistent data storage device. The processing system 300 may also include one or more cache memories (not shown) that provide temporary storage of at least some program code in order to reduce the number of times program code must be retrieved from the bulk storage device 310 during execution.

Input/output (I/O) devices depicted as an input device 312 and an output device 314 optionally can be coupled to the data processing system. Examples of input devices may include, but are not limited to, a keyboard, a pointing device such as a mouse, or the like. Examples of output devices may include, but are not limited to, a monitor or a display, speakers, or the like. Input and/or output devices may be coupled to the data processing system either directly or through intervening I/O controllers.

In an embodiment, the input and the output devices may be implemented as a combined input/output device (illustrated in FIG. 10 with a dashed line surrounding the input device 312 and the output device 314). An example of such a combined device is a touch sensitive display, also sometimes referred to as a “touch screen display” or simply “touch screen”. In such an embodiment, input to the device may be provided by a movement of a physical object, such as e.g. a stylus or a finger of a user, on or near the touch screen display.

A network adapter 316 may also be coupled to the data processing system to enable it to become coupled to other systems, computer systems, remote network devices, and/or remote storage devices through intervening private or public networks. The network adapter may comprise a data receiver for receiving data that is transmitted by said systems, devices and/or networks to the data processing system 300, and a data transmitter for transmitting data from the data processing system 300 to said systems, devices and/or networks. Modems, cable modems, and Ethernet cards are examples of different types of network adapter that may be used with the data processing system 300.

As pictured in FIG. 10, the memory elements 304 may store an application 318. In various embodiments, the application 318 may be stored in the local memory 308, he one or more bulk storage devices 310, or separate from the local memory and the bulk storage devices. It should be appreciated that the data processing system 300 may further execute an operating system (not shown in FIG. 10) that can facilitate execution of the application 318. The application 318, being implemented in the form of executable program code, can be executed by the data processing system 300, e.g., by the processor 302. Responsive to executing the application, the data processing system 300 may be configured to perform one or more operations or method steps described herein.

Various embodiments of the invention may be implemented as a program product for use with a computer system, where the program(s) of the program product define functions of the embodiments (including the methods described herein). In one embodiment, the program(s) can be contained on a variety of non-transitory computer-readable storage media, where, as used herein, the expression “non-transitory computer readable storage media” comprises all computer-readable media, with the sole exception being a transitory, propagating signal. In another embodiment, the program(s) can be contained on a variety of transitory computer-readable storage media. Illustrative computer-readable storage media include, but are not limited to: (i) non-writable storage media (e.g., read-only memory devices within a computer such as CD-ROM disks readable by a CD-ROM drive, ROM chips or any type of solid-state non-volatile semiconductor memory) on which information is permanently stored; and (ii) writable storage media (e.g., flash memory, floppy disks within a diskette drive or hard-disk drive or any type of solid-state random-access semiconductor memory) on which alterable information is stored. The computer program may be run on the processor 302 described herein.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of embodiments of the present invention has been presented for purposes of illustration, but is not intended to be exhaustive or limited to the implementations in the form disclosed. Many modifications and variations will be apparent to those of ordinary skill in the art without departing from the scope of the present invention. The embodiments were chosen and described in order to best explain the principles and some practical applications of the present invention, and to enable others of ordinary skill in the art to understand the present invention for various embodiments with various modifications as are suited to the particular use contemplated.

1. A system for performing simulations on a digital twin of a telecommunication network, the system including at least one processor configured to:
determine a minimum assessment accuracy with respect to one or more performance indicators and/or determine a maximum assessment duration,
select a simulation model for each of a plurality of components of the digital twin based on at least one of the minimum assessment accuracy and the maximum assessment duration,
assemble the selected simulation models into the digital twin, and
perform the simulations on the digital twin.

2. A system as claimed in claim 1, wherein the at least one processor is configured to select the simulation model for each of the plurality of components of the digital twin based on at least one of the minimum assessment accuracy and the maximum assessment duration by determining a quantity of the plurality of components based on at least one of the minimum assessment accuracy and the maximum assessment duration and selecting a simulation model for each of the plurality of components.

3. A system as claimed in claim 1, wherein for at least one of the plurality of components, a component type of a respective component is associated with a plurality of simulation models of different degrees of complexity, and wherein the at least one processor is configured to select the simulation model for each of the plurality of components of the digital twin based on at least one of the minimum assessment accuracy and the maximum assessment duration by selecting at least one simulation model for the at least one component from the plurality of simulation models based on at least one of the minimum assessment accuracy and the maximum assessment duration.

4. A system as claimed in claim 1, wherein the at least one processor is configured to:
perform the simulations on the digital twin to determine one or more network configuration settings of the telecommunication network, and
configure the telecommunication network with the one or more network configuration settings.

5. A system as claimed in claim 1, wherein the at least one processor is configured to:
select a problem definition from a plurality of problem definitions, each of the plurality of problem definitions specifying one or more configuration parameters to be optimized and one or more corresponding performance indicators,
select the simulation model for each of the plurality of components of the digital twin further based on the selected problem definition, and
select one or more configuration parameters for the simulations from the selected problem definition.

6. A system as claimed in claim 5, wherein the selected problem definition includes the minimum assessment accuracy and/or the maximum assessment duration.

7. A system as claimed in claim 1, wherein the at least one processor is configured to:
assemble simulation models into different digital twin candidates,
perform multiple simulations on each of the assembled different digital twin candidates to determine training samples,
generate, for a plurality of digital twin candidates, based on the training samples, a utility function with respect to the one or more performance indicators, the plurality of digital twin candidates including the assembled different digital twin candidates,
generate, for the plurality of digital twin candidates, a cost function based on the training samples, and
select the simulation model for each of the plurality of components of the digital twin by applying the utility function to the minimum assessment accuracy and/or by applying the cost function to the maximum assessment duration.

8. A system as claimed in claim 7, wherein the training samples include values of the one or more performance indicators and the at least one processor is configured to generate the cost function and/or the utility function based on the values of the one or more performance indicators.

9. A system as claimed in claim 1, wherein the at least one processor is configured to select the simulation model for each of the plurality of components by selecting a digital twin candidate from a plurality of digital twin candidates based on at least one of the minimum assessment accuracy and the maximum assessment duration and further based on expert knowledge.

10. A system as claimed in claim 1, wherein the at least one processor is configured to select the simulation model for each of the plurality of components of the digital twin based on the maximum assessment duration such that the simulations on the digital twin will have a maximized assessment accuracy without exceeding the maximum assessment duration.

11. A system as claimed in claim 1, wherein the at least one processor is configured to select the simulation model for each of the plurality of components of the digital twin based on the minimum assessment accuracy such that the simulations on the digital twin will have a minimized assessment duration while satisfying the minimum assessment accuracy.

12. A system for generating utility and cost functions for digital twin candidates of a telecommunication network, the system including at least one processor configured to:
assemble simulation models into different digital twin candidates of a telecommunication network,
perform multiple simulations on each of the assembled different digital twin candidates to determine training samples,
generate, for a plurality of digital twin candidates, based on the training samples, a utility function with respect to one or more performance indicators, the plurality of digital twin candidates including the assembled different digital twin candidates,
generate, for the plurality of digital twin candidates, a cost function based on the training samples, and
store in a memory information specifying the cost and utility functions generated for the plurality of digital twin candidates.

13. A computer-implemented method of performing simulations on a digital twin of a telecommunication network, the method comprising:
determining a minimum assessment accuracy with respect to one or more performance indicators and/or determining a maximum assessment duration;
selecting a simulation model for each of a plurality of components of the digital twin based on at least one of the minimum assessment accuracy and the maximum assessment duration;
assembling the selected simulation models into the digital twin; and
performing the simulations on the digital twin.

14. A computer-implemented method of generating utility and cost functions for digital twin candidates of a telecommunication network, the method comprising:
assembling simulation models into different digital twin candidates of a telecommunication network;
performing multiple simulations on each of the assembled different digital twin candidates to determine training samples;
generating, for a plurality of digital twin candidates, based on the training samples, a utility function with respect to one or more performance indicators, the plurality of digital twin candidates including the assembled different digital twin candidates;
generating, for the plurality of digital twin candidates, a cost function based on the training samples; and
storing, in a memory, information specifying the cost and utility functions generated for the plurality of digital twin candidates.

15. A computer program or suite of computer programs including at least one software code portion or a computer program product storing at least one software code portion, the software code portion, when run on a computer system, being configured for performing the method of claim 13.
